(19) United States
(12) Patent Application Publication
(10) Pub. No.: US 2026/0248020 A1
(43) Pub. Date: Aug. 20, 2026

(54) MANUFACTURING METHOD FOR A MOUNTING BOARD AND MOUNTING BOARD

(71) Applicant: Sony Semiconductor Solutions Corporation, Kanagawa (JP)

(72) Inventor: Toshiyuki Sasaki, Tokyo (JP)

(73) Assignee: Sony Semiconductor Solutions Corporation, Kanagawa (JP)

(21) Appl. No.: 19/164,850

(22) PCT Filed: Oct. 5, 2023
(86) PCT No.: PCT/JP2023/036313

§ 371 Date: Sep. 12, 2025

(30) Foreign Application Priority Data
Mar. 29, 2023 (JP) 2023-052548

(51) Int. Cl. H10W 74/01; H10W 70/68; H10W 74/10; H10W 74/15; H10W 90/00

(52) U.S. Cl. CPC H10W 74/012; H10W 70/681; H10W 74/114; H10W 74/121; H10W 74/15; H10W 90/724

(57) ABSTRACT

There is provided a manufacturing method for a mounting board including: forming a hole in a mounting region of a substrate, the hole penetrating the substrate in a thickness direction of the substrate, the substrate having a first surface and a second surface and having the mounting region on the first surface; mounting an electronic component on the mounting region by disposing a main body of the electronic component so that the main body is spaced apart from the substrate and faces the hole, the electronic component having the main body and a connection part; and forming a coating layer that covers the entire electronic component including a gap between the substrate and the electronic component by applying a coating agent toward the electronic component from a side of the first surface with the first surface oriented upwards.

### CROSS REFERENCE TO RELATED APPLICATIONS

This application claims the benefit of Japanese Priority Patent Application JP 2023-052548 filed Mar. 29, 2023, the entire contents of which are incorporated herein by reference.

### TECHNICAL FIELD

The present technology relates to a manufacturing method for a mounting board with electronic components mounted on a substrate and such a mounting board.

### BACKGROUND ART

Electronic components used for a variety of control apparatuses and the like are typically mounted on the control apparatus in the form of a mounting board in which the electronic components are surface-mounted on a substrate. There is a risk that an electrical short-circuit may occur if the mounting board accidentally gets wet or a foreign matter enters the mounting board and mixes with moisture generated due to condensation. A method of coating electronic components surface-mounted on a substrate with a resin for insulation has been widely used for avoiding such a risk.

In the method of coating electronic components with a resin, air-bubbles easily remain under the electronic components at the time of coating. If load over time such as repeated expansion and contraction due to changes in temperature is added to the electronic components covered with a coating layer including those air-bubbles, the coating layer may have cracks. The cracks may cause invasion of moisture or foreign matters for example into the electronic components, which leads to operation failures or malfunctions of the electronic components.

For example, according to Patent Literature 1, a through-hole is formed in a portion of a substrate where an electronic component is to be mounted, the electronic component is mounted on the substrate, and the electronic component is molded by immersing the substrate with the electronic component mounted in a resin. The electronic component is immersed in the resin in an attitude in which the substrate on which the electronic component is mounted is upright, and the through-hole is formed in a portion of the substrate which corresponds to an upper back surface portion of the electronic component in such an attitude. Forming the through-hole in this manner allows air-bubbles in a gap between the substrate and the electronic component to escape through the through-hole when molding the electronic component with the resin, which can prevent pin-holes generated by air-bubbles.

### CITATION LIST

### Patent Literature

PTL 1: Japanese unexamined utility model application publication No. SHO 61-38973

### SUMMARY

### Technical Problem

As described above, it is desirable to apply a resin coating for an electronic component without generating air-bubbles between the electronic component and a substrate.

In view of the above-mentioned circumstances, the present technology has been made for providing a manufacturing method for a mounting board that suppresses generation of air-bubbles in a coating layer between an electronic component and a substrate and such a mounting board.

### Solution to Problem

According to an embodiment of the present technology, there is provided a manufacturing method for a mounting board including:
forming a hole in a mounting region of a substrate, the hole penetrating the substrate in a thickness direction of the substrate, the substrate having a first surface and a second surface and having the mounting region on the first surface;
mounting an electronic component on the mounting region by disposing a main body of the electronic component so that the main body is spaced apart from the substrate and faces the hole, the electronic component having the main body and a connection part; and
forming a coating layer that covers the entire electronic component including a gap between the substrate and the electronic component by applying a coating agent toward the electronic component from a side of the first surface with the first surface oriented upwards.

With such a configuration, air in the gap between the substrate and the electronic component does not easily escape to the outside of the substrate from the side of the second surface through the hole at the time of applying the coating agent, and generation of air-bubbles in the coating layer disposed in the gap between the substrate and the electronic component is suppressed. Accordingly, even if load over time such as repeated expansion and contraction due to changes in temperature is added to the mounting board, the coating layer does not easily have cracks. Thus, the quality of the electronic component can be stably maintained high.

The coating agent may enter at least a part of the hole at the time of forming the coating layer.

The manufacturing method for a mounting board may further include suctioning air in the gap from a side of the second surface through the hole at the time of forming the coating layer.

The coating agent may have viscosity of 20 millipascal seconds or more.

The coating layer may include a gap coating layer and a cover coating layer, and
the forming the coating layer may include
forming the gap coating layer at least in the gap by applying a gap coating agent toward the electronic component from the side of the first surface, and
forming the cover coating layer that covers the entire electronic component including the gap coating layer by applying a cover coating agent toward the electronic component from the side of the first surface, the cover coating agent having viscosity higher than viscosity of the gap coating agent.

The coating layer may include a wall-like coating layer and a cover coating layer, and
the forming the coating layer may include
forming the wall-like coating layer that surrounds the electronic component by applying a wall coating agent to the substrate from the side of the first surface so as to surround the mounting region, and
forming the cover resin layer that covers the entire electronic component including the gap by applying a cover coating agent to a region surrounded by the wall-like coating layer from the side of the first surface, the cover coating agent having viscosity lower than viscosity of the wall coating agent.

The substrate may have a mounting region on the second surface, the mounting region not overlapping the mounting region on the first surface in the thickness direction, the manufacturing method further including:
forming a hole in the mounting region on the second surface of the substrate, the hole penetrating the substrate in the thickness direction;
mounting an electronic component to be mounted on the second surface on the mounting region on the second surface by disposing a main body of the electronic component to be mounted on the second surface so that the main body is spaced apart from the substrate and faces the hole in the mounting region on the second surface, the electronic component to be mounted on the second surface having the main body and a connection part; and
forming a coating layer that covers the entire electronic component to be mounted on the second surface including a gap between the substrate and the electronic component to be mounted on the second surface by applying a coating agent toward the electronic component to be mounted on the second surface from a side of the second surface with the second surface oriented upwards.

The manufacturing method for a mounting board may further include heating the substrate at the time of forming the coating layer.

The applying the coating agent may be jet coating, and a dispensing direction of the coating agent may be perpendicular to the first surface.

According to another embodiment of the present technology, there is provided a mounting board including a substrate, an electronic component, and a coating layer.

The substrate has a first surface and a second surface.

The substrate has a mounting region on the first surface and has a hole in the mounting region, the hole penetrating the substrate in a thickness direction of the substrate.

The electronic component has the main body and a connection part.

The electronic component is mounted on the mounting region by disposing the main body so that the main body is spaced apart from the substrate and faces the first hole.

The coating layer is formed on the first surface and covers the entire electronic component including a gap between the substrate and the electronic component.

The coating layer may enter at least a part of the hole.

The coating layer may include a gap coating layer that is disposed including the gap, and a cover coating layer that covers the entire electronic component including the gap coating layer.

The coating layer may include a wall-like coating layer having a wall-like shape that surrounds the electronic component disposed on the substrate, and a cover coating layer that is located inside a region surrounded by the wall-like coating layer and covers the electronic component.

The substrate may have a mounting region on the second surface and have a hole in the mounting region on the second surface, the mounting region not overlapping the mounting region on the first surface in the thickness direction, the hole penetrating the substrate in the thickness direction of the substrate, and
the mounting board may further include:
an electronic component to be mounted on the second surface that has a main body and a connection part and is mounted on a mounting region on the second surface by disposing the main body so that the main body is spaced apart from the substrate and faces the hole in the mounting region on the second surface; and
a coating layer that is formed on the second surface and covers the entire electronic component to be mounted on the second surface including a gap between the substrate and the electronic component to be mounted on the second surface.

### BRIEF DESCRIPTION OF DRAWINGS

FIG. 1 is a schematic cross-sectional view of a mounting board according to a first embodiment of the present technology.

(A) of FIG. 2 is a perspective view of a chip resistor that is an example of an electronic component mounted on the mounting board and (B) of FIG. 2 is a plan view showing a positional relationship example between a hole formed in a substrate and an electronic component (chip resistor) mounted.
(A) of FIG. 3 is a side view of an IC chip with leads that is an example of the electronic component mounted on the mounting board, (B) and (C) of FIG. 3 are plan views each showing a positional relationship example between the hole formed in the substrate and the electronic component (IC chip with leads) to be mounted, and (D) of FIG. 3 is a perspective view of an IC chip with no leads that is another example of the electronic component.

FIG. 4 is a flowchart showing a manufacturing method for the mounting board according to the first embodiment.

(A) to (D) of FIG. 5 are schematic cross-sectional views each showing a manufacturing process for the mounting board according to the first embodiment.

FIG. 6 is a plan view for describing an application method for a coating agent, which shows a movement path of a nozzle at the time of applying a coating agent.

FIG. 7 is a schematic cross-sectional view of a mounting board according to a second embodiment.

FIG. 8 is a flowchart showing a manufacturing method for a mounting board according to the second embodiment.

FIG. 9 is a flowchart showing a manufacturing method for a mounting board according to a third embodiment.

FIG. 10 is a view showing a manufacturing process for a mounting board according to a third embodiment.

FIG. 11 is a flowchart showing a manufacturing method for a mounting board according to a fourth embodiment.

FIG. 12 is a view showing a manufacturing process for the mounting board according to the fourth embodiment.

FIG. 13 is a plan view for describing an application method for a coating agent according to the fourth embodiment, in which (A) shows a movement path of a nozzle at the time of applying a wall coating agent and (B) shows a movement path of a nozzle at the time of applying a cover coating agent.

FIG. 14 is a plan view schematically showing a coating state of the electronic component with a coating agent on the mounting board according to the fourth embodiment.

FIG. 15 is a view describing a manufacturing method for a mounting board according to a fifth embodiment.

FIG. 16 is a view describing a manufacturing method for a mounting board according to a sixth embodiment.

### DESCRIPTION OF EMBODIMENTS

Hereinafter, embodiments according to the present technology will be described with reference to the drawings. In the following description, previously described configurations will be denoted by similar reference signs and descriptions thereof will be omitted in some cases.

### First Embodiment

### Configuration of Mounting Board

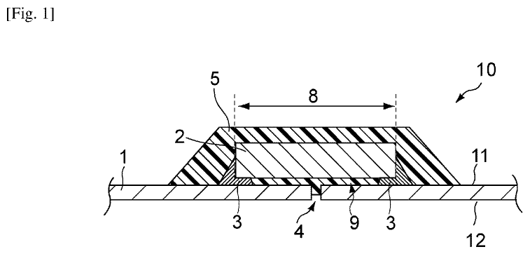

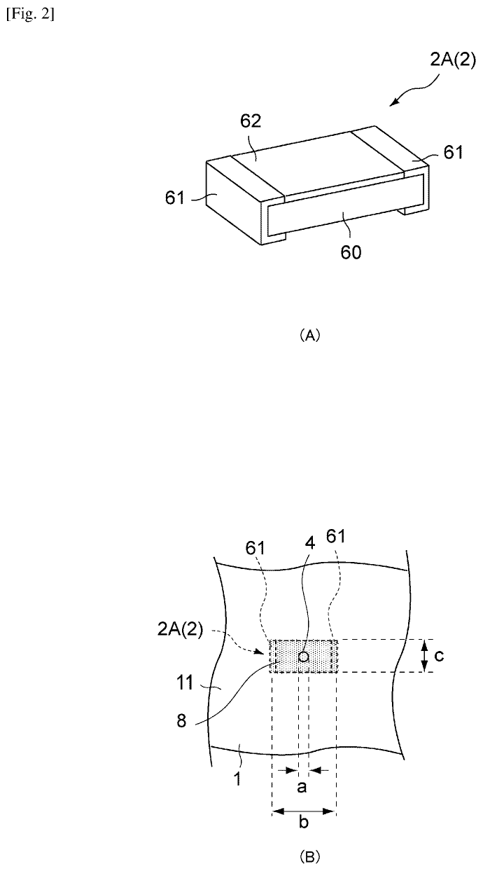

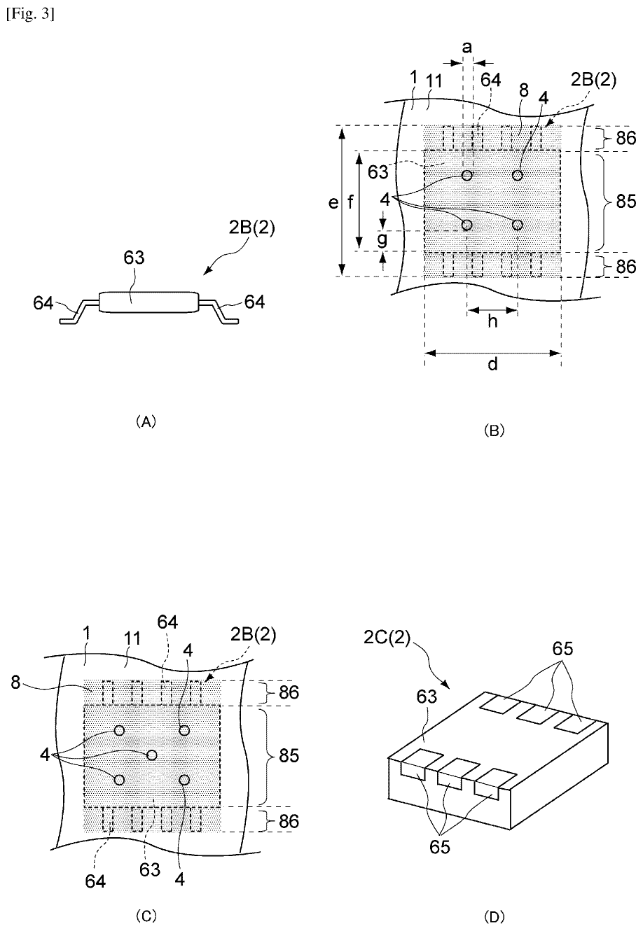

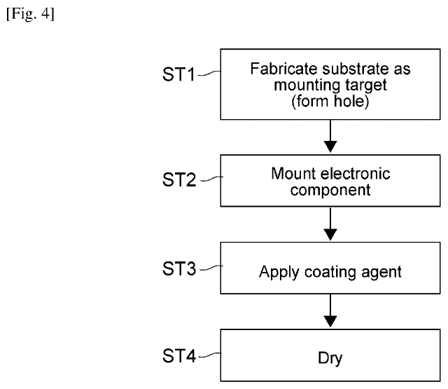

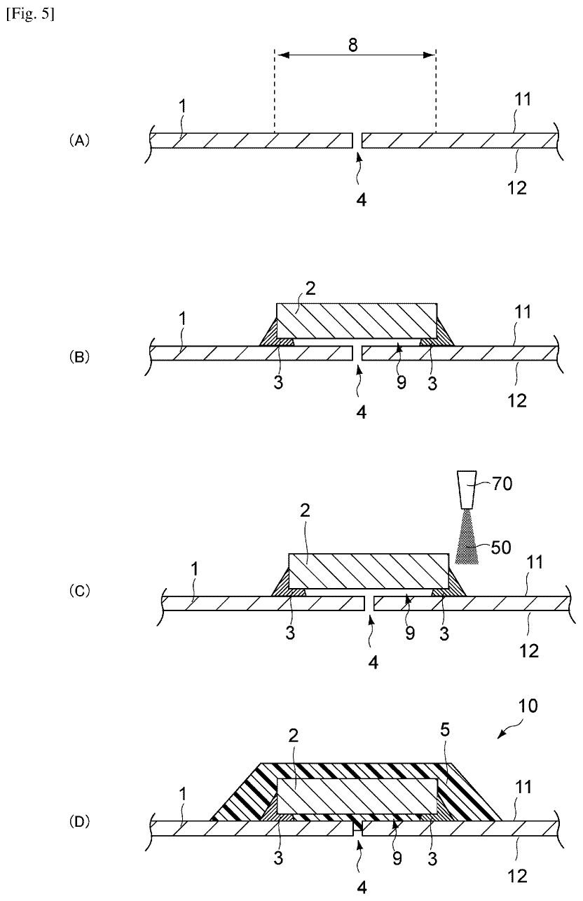

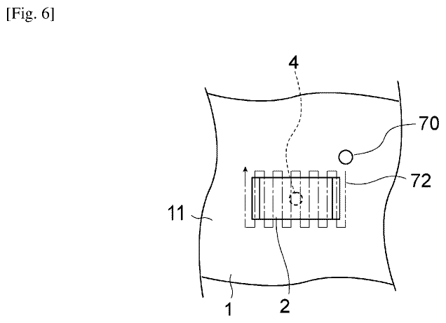

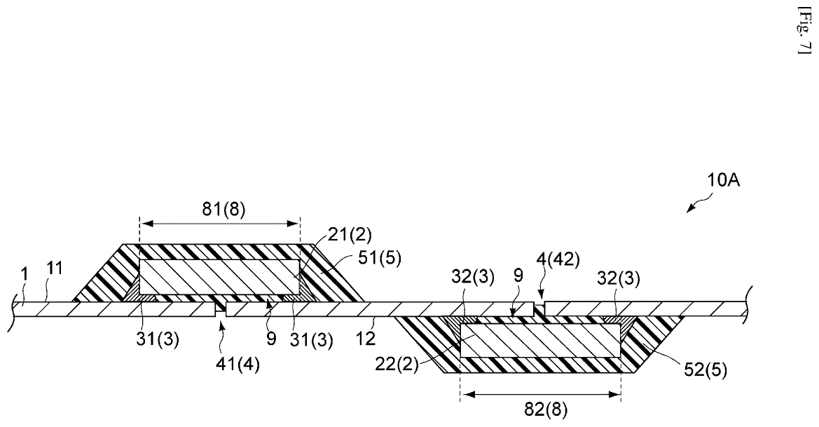

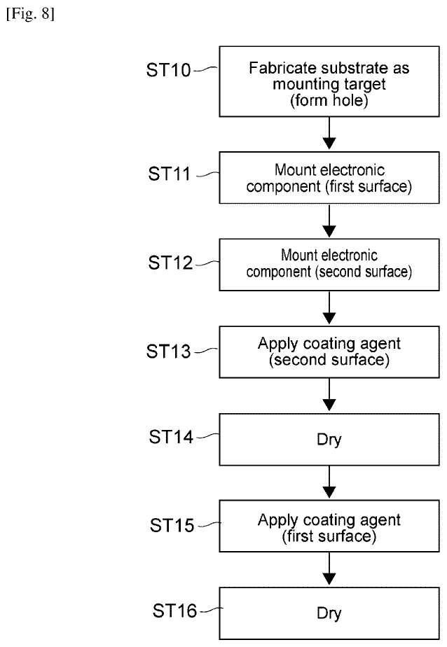

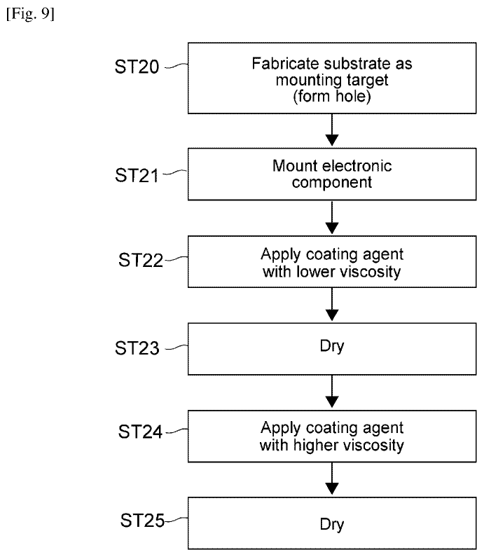

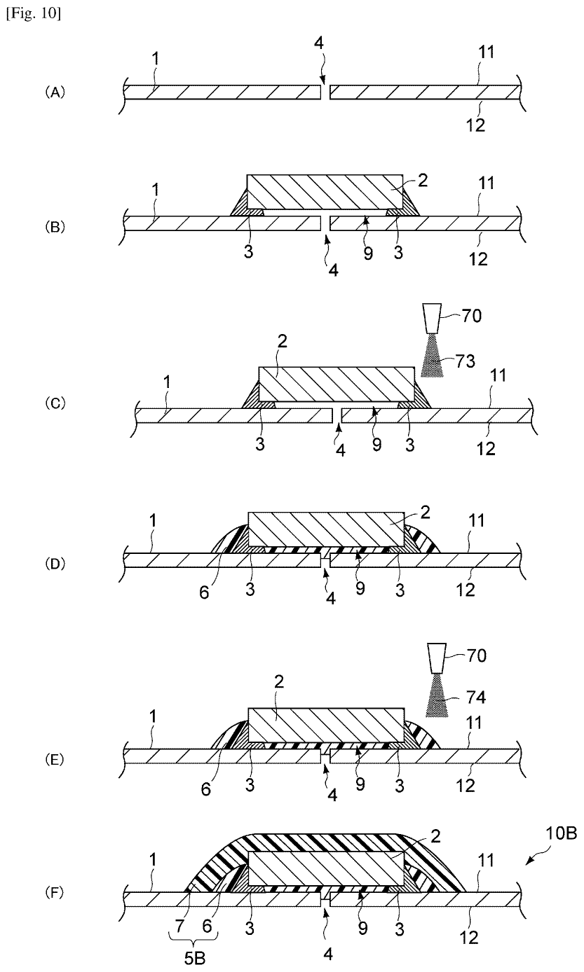

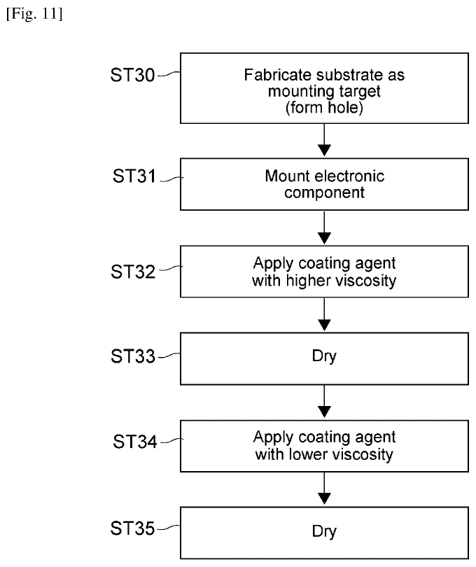

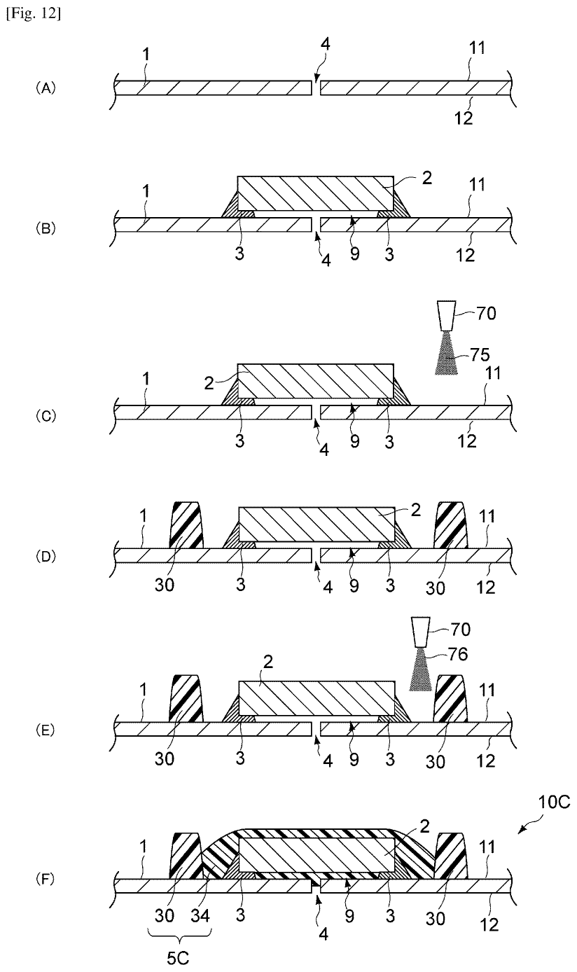

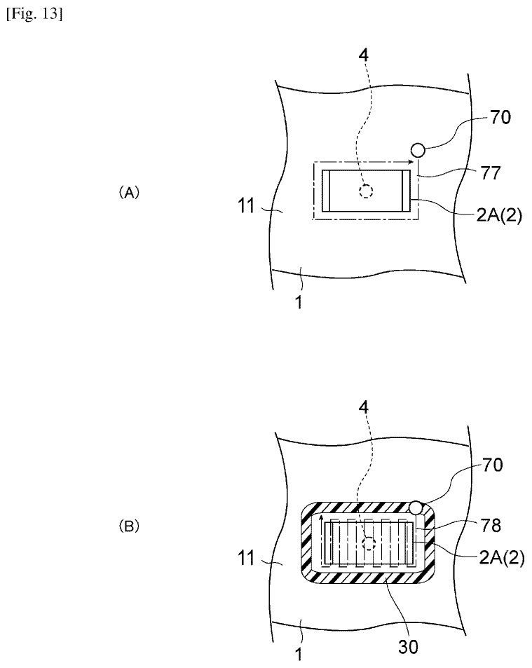

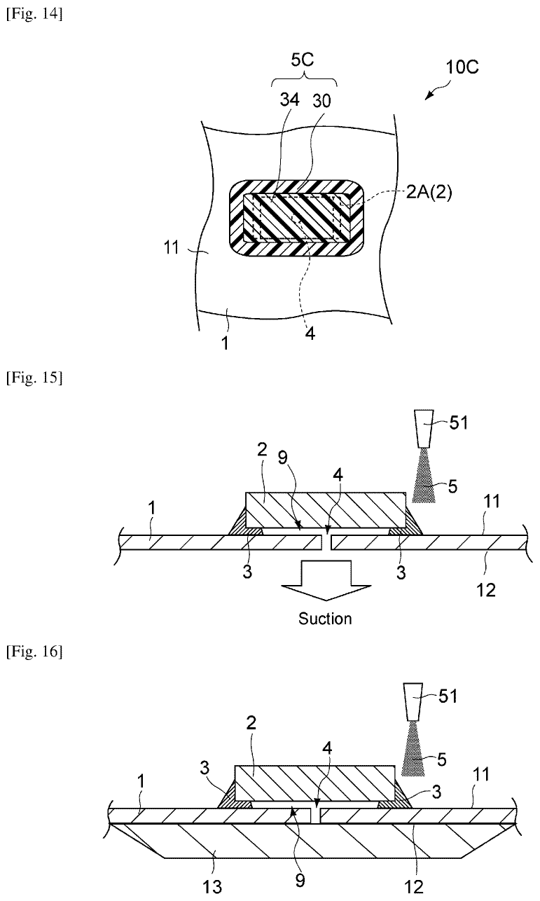

FIG. 1 is a schematic partial cross-sectional view of a mounting board 10 according to a first embodiment. As shown in FIG. 1, the mounting board 10 includes a substrate 1 having a hole 4, solder 3, an electronic component 2, and a coating layer 5.

The substrate 1 is a substrate as a mounting target on which a variety of electronic components 2 are to be surface-mounted. The substrate 1 has a first surface 11 and a second surface 12. The substrate 1 has a mounting region 8 where the variety of electronic components 2 are mounted. In the mounting board 10 shown in FIG. 1, the mounting region 8 is set on the first surface 11. The mounting region 8 has lands (not shown) where connection parts such as external electrodes and leads of the electronic component 2, which will be described later, are electrically connected with the solder 3. The mounting region 8 is a region surrounding the outline of a projection view of the electronic component as the electronic component is projected onto the substrate 1 when the electronic component as a product to be mounted is mounted on the substrate 1. In (B) of FIG. 2, (B) of FIG. 3, and (C) of FIG. 3 which will be described later, the mounting region 8 is shown, filled with tiny dots. The hole 4 is formed in the mounting region 8.

It should be noted that although the mounting board 10 for single-sided mounting in which the electronic component 2 is mounted on one surface (here, the first surface 11) of the substrate 1 is described as an example in the present embodiment, a mounting board for double-sided mounting in which the electronic component 2 is mounted on both surfaces (first surface 11 and second surface 12) of the substrate 1 may be employed as in a second embodiment which will be described later. In the second embodiment, for the sake of convenience, in order to distinguish the electronic component 2 mounted on the first surface 11 from the electronic component 2 mounted on the second surface 12, the electronic component, the coating layer, the solder, the mounting region, and the hole formed in the mounting region that are provided in the first surface 11 will be referred to with the prefix “first”, and the electronic component, the coating layer, the solder, the mounting region, and the hole formed in the mounting region that are provided in the second surface 12 will be referred to with the prefix “second”. In the first embodiment and the third and fourth embodiments which will be described later, single-sided mounting in which the electronic component 2 is mounted on the first surface 11 will be taken as an example and described without the prefix “first”. It should be noted that a double-sided mounting configuration may be employed also in the third and fourth embodiments.

In the present specification, a view of the substrate 1 in a thickness direction of the substrate 1 from on the side of the first surface 11 (or the side of the second surface 12) will be referred to as a planar view. The thickness direction is a direction perpendicular to the substrate 1.

As shown in FIG. 1 and (B) of FIG. 5, the electronic component 2 is mounted on the substrate 1 with the solder 3, such that a gap 9 is generated between a main body of the electronic component 2 (which will be described later in detail) and the substrate 1. The gap 9 is a narrow gap of approximately 0.1 mm to 0.3 mm. Therefore, the gap 9 between the electronic component 2 and the substrate 1 is not sufficiently filled with the coating agent and air-bubbles are easily generated at the time of covering the entire electronic component 2 with a coating agent. With the air-bubbles, the coating layer has cracks easily when load over time such as repeated expansion and contraction due to changes in temperature is added to the mounting board 10. If the coating layer has cracks, moisture or foreign matters for example easily enter from the outside and a short-circuit occurs due to the moisture or foreign matters for example with higher possibility. Therefore, the quality of the electronic component cannot be stably maintained high.

In contrast, in the present technology, the hole 4 is formed in the mounting region 8 for the electronic component 2, such that air-bubbles are not easily generated in the gap 9 at the time of applying a coating material. Therefore, generation of cracks in the coating layer 5 can be effectively suppressed. It will be described later in detail.

The hole 4 is formed in the mounting region 8 as a through-hole penetrating the substrate 1. In the mounting board 10, the first surface 11 of the substrate 1 and the electronic component 2 are spaced apart from each other and the hole 4 and the main body of the electronic component 2 are positioned facing each other. As shown in FIG. 1, in the present embodiment, the coating agent enters a part of the hole 4 and the coating layer 5 is partially disposed in the hole 4 at the time of applying the coating agent. The coating layer 5 disposed in the gap 9 and the coating layer 5 disposed in the hole 4 are continuous with each other with no gap.

Since the substrate 1 has the hole 4 penetrating the substrate 1 in the thickness direction, expansion and contraction force in a direction to the second surface 12 from the first surface 11 (downward direction in FIG. 1) can escape through the hole 4 when the coating layer 5 expands and contracts due to changes in temperature for example in a case where the mounting board 10 is used, mounted on a control apparatus. Accordingly, stress applied to the solder 3 on the electronic component 2 can be reduced and the occurrence of for example separation of the electronic component 2 from the substrate 1 due to cracks in the solder 3 can be effectively suppressed.

It should be noted that although in the present embodiment, the mode on which the coating layer 5 partially enters the hole 4 has been described, a mode on which the coating layer enters the entire hole 4 or a mode on which the coating layer 5 does not enter the hole 4 may be employed.

In order to suppress separation of the electronic component 2 from the substrate 1, the coating layer 5 is favorably disposed in the hole 4, such that an anchor effect can be obtained.

In order to suppress separation of the electronic component 2 from the substrate 1 while effectively suppressing the above-mentioned stress, the coating layer 5 is favorably partially disposed in the hole 4 as shown in FIG. 1.

In the present embodiment, in a case where the electronic component (mounted component) mounted on the substrate 1 is a minute electronic component, the hole 4 does not need to be formed in the mounting region 8 for the electronic component. The minute electronic component refers to an electronic component with a size of 0.6 mm*0.3 mm or less in the planar view, for example. With such a minute electronic component, the hole 4 does not need to be formed because the size of the gap 9 between the substrate 1 and the electronic component 2 in a plane direction is small and generation of air-bubbles at the time of applying the coating agent is unlikely to occur.

On the other hand, the hole 4 is formed in the mounting region 8 for the electronic component 2 larger than 0.6 mm*0.3 mm. Examples of the electronic component whose size in the planar view is larger than 0.6 mm*0.3 mm can include a resistor, a ceramic capacitor, and an integrated circuit (IC) chip. Typically, the IC chip is an electronic component larger in size than the resistor and the ceramic capacitor in the planar view. A plurality of holes 4 is favorably provided in a mounting region of such an electronic component larger in size. The holes 4 are arranged so as to avoid wires and lands of the substrate 1. The holes 4 will be described later in detail.

### Electronic Component Example

Hereinafter, a chip resistor 2A, an IC chip 2B with leads, and an IC chip 2C with no leads will be described as specific examples of the electronic component with reference to FIGS. 2 and 3. They will be referred to as electronic components 2 in a case where they do not especially need to be distinguished.

(A) of FIG. 2 is a perspective view of the chip resistor 2A that is an example of the electronic component mounted on the substrate 1. (B) of FIG. 2 is a plan view showing a positional relationship example between the hole 4 provided in the substrate 1 and the electronic component (chip resistor 2A) to be mounted.

As shown in (A) of FIG. 2, the chip resistor 2A includes a main body 60 obtained by forming a metal film on the substrate as a resistor, a protection film 62 that covers the main body 60, and external electrodes 61 as a pair of connection parts. The chip resistor 2A has an outer shape that is a substantially rectangular parallelepiped shape and has a configuration in which the external electrodes 61 are provided on a pair of surfaces facing each other. In the mounting board 10 in which the chip resistor 2A is mounted on the substrate 1, the external electrodes 61 electrically connect to lands on the substrate 1 with the solder 3. When the chip resistor 2A is mounted with the solder 3, the main body 60 is positioned apart from the substrate 1 and forms the gap 9 (see FIG. 1).

Examples of a representative size in the planar view of the chip resistor 2A as a target of forming the hole 4 in the mounting region 8 include 1.0 mm*0.5 mm, 1.6 mm*0.8 mm, 2.0 mm*1.25 mm, 3.2 mm*1.6 mm, 3.2 mm*2.5 mm, 4.5 mm*3.2 mm, 5.0 mm*2.5 mm, and 6.0 mm*3.0 mm as they are expressed as the horizontal length b * the vertical length c, referring to (B) of FIG. 2. As shown in (B) of FIG. 2, a single hole 4 is formed at substantially the center of the mounting region 8 as to the chip resistor 2A with a size of 3.2 mm*2.5 mm or less. On the other hand, typically two holes 4 are formed as to the chip resistor 2A larger than 3.2 mm*2.5 mm. A hole size and a hole arrangement in which a plurality of holes is formed will be described later in detail.

Moreover, in a case where the electronic component is a ceramic capacitor, examples of a representative size in the planar view of the ceramic capacitor as a target of forming the hole 4 in the mounting region 8 include 1.0 mm*0.5 mm, 1.6 mm*0.8 mm, 2.0 mm*1.25 mm, 3.2 mm*1.6 mm, 3.2 mm*2.5 mm, 4.5 mm*3.2 mm, and 5.7 mm*5.0 mm as they are expressed as the horizontal length b * the vertical length c, referring to (B) of FIG. 2. A single hole 4 is formed substantially at the center of its mounting region 8 as to a ceramic capacitor with a size of 3.2 mm*2.5 mm or less. On the other hand, typically two holes 4 are formed as to a ceramic capacitor larger than 3.2 mm*2.5 mm.

(A) of FIG. 3 is a side view of the IC chip 2B with leads that is an example of the electronic component mounted on the substrate 1. (B) and (C) of FIG. 3 are plan views showing a positional relationship example between holes 4 provided in the substrate 1 and the electronic component (IC chip 2B with leads) to be mounted. (D) of FIG. 3 is a perspective view of the IC chip 2C with no leads that is an example of the electronic component mounted on the substrate 1. It should be noted that here, the IC chip with leads having a shape in which leads protrude from a pair of sides of the rectangular outer shape, which are opposite to each other, is described as an example, though not limited thereto. For example, a quad flat package (QFP) having a shape in which leads protrude from four sides may be employed.

As shown in (A) of FIG. 3, the IC chip 2B with leads includes a main body 63 and leads 64 as connection parts which are provided projected from the main body 63. In the mounting board 10 on which the IC chip 2B with leads is mounted on the substrate 1, the leads 64 electrically connect to lands on the substrate 1 with the solder 3. The main body 63 is positioned apart from the substrate 1, such that a gap 9 is formed.

Referring to (B) of FIG. 3, as to a typical size of the IC chip 2B with leads in the planar view, a horizontal length d is 1 mm to 50 mm, a vertical length f of the main body 63 is 1 mm to 50 mm, and a vertical length e of the entire IC chip 2B with leads is 2 mm to 60 mm. A plurality of holes 4 is provided in mounting regions 8 of the IC chips 2B and 2C larger in size than the chip resistor 2A or the like. In the example shown in (B) of FIG. 3, four holes 4 are arranged in a grid form of vertically two holes and horizontally two holes. In the example shown in (C) of FIG. 3, a single hole 4 is arranged at substantially the center of the mounting region 8 and four holes 4 are arranged in a grid form of vertically two holes and horizontally two holes so as to surround the hole 4 at the center, that is, a total of five holes 4 are arranged. The number of holes is set as appropriate depending on the size of the IC chip (electronic component) and the viscosity of the coating agent. The hole size and the hole arrangement in a case where a plurality of holes is formed will be described later in detail.

Moreover, the IC chip may be an IC chip 2C with no leads as shown in (D) of FIG. 3. The IC chip 2C with no leads includes a main body 63 and external electrodes 65 as the connection parts. In the mounting board 10 in which the IC chip 2C with no leads is mounted on the substrate 1, the upper surface in (D) of FIG. 3 is located facing the first surface of the substrate 1, and the external electrodes 65 electrically connect to lands on the substrate 1 with the solder 3. The main body 63 is positioned apart from the substrate 1 so that the gap 9 is formed when the IC chip 2C with no leads is mounted on the substrate 1 with the solder 3.

As shown in (B) and (C) of FIG. 3, in the IC chip 2B with leads, the mounting region 8 includes a region 85 corresponding to the main body 63 and regions 86 corresponding to the leads 64. The region 85 corresponding to the main body 63 is a region as the main body 63 is projected onto the substrate 1. In the present embodiment, the region 85 corresponding to the main body 63 is a rectangular shape in the planar view. The region corresponding to the main body can also be said to be a region corresponding to a portion in which the electronic component 2 forms the gap 9 together with the substrate 1.

In a case where the electronic component 2 to be mounted has leads, the hole 4 may be formed in the regions 86 corresponding to the leads 64. However, in order to cause the air in the gap 9 to escape effectively for forming no air-bubbles, the hole 4 is more favorably formed in the region 85 corresponding to the main body 63 that forms the gap 9 together with the substrate 1. In addition, for a similar purpose, the hole 4 is favorably formed only in the region 85 corresponding to the main body 63 as shown in (B) and (C) of FIG. 3.

It should be noted that since the IC chip 2C with no leads, the chip resistor 2A, or the like has a shape without legs like leads in contrast to the IC chip 2B with leads, the region corresponding to the main body is the same as the mounting region 8.

### Manufacturing Method for Mounting Board

Next, a manufacturing method for the mounting board 10 will be described. FIG. 4 is a flowchart showing the manufacturing method for the mounting board 10. FIG. 5 is a schematic cross-sectional view showing a manufacturing process for the mounting board 10. FIG. 6 is a plan view showing a state in which a coating agent 50 is applied to the substrate 1 on which the electronic component 2 is mounted, which shows a movement path example of a nozzle.

Hereinafter, the manufacturing method for the mounting board 10 will be described with reference to FIGS. 5 and 6 following the flowchart of FIG. 4. Here, an example in which the electronic component is a chip resistor and a single hole 4 is formed in a mounting region of the substrate 1 on which the chip resistor is mounted is described. However, the electronic component may be an IC chip and a plurality of holes 4 may be formed in the mounting region 8 of the IC chip. It should be noted that here, it will be referred to as the electronic component 2, not the chip resistor. The same applies to other embodiments which will be described later.

As shown in (A) of FIG. 5, first of all, a substrate 1 is prepared and a hole 4 is formed to penetrate the substrate 1 in a thickness direction in a mounting region 8 set in a first surface 11 of the substrate 1 (ST1). The hole 4 can be formed by drilling. The mounting region 8 is a region where the electronic component 2 is mounted on the first surface 11 of the substrate 1.

Next, as shown in (B) of FIG. 5, the electronic component 2 is disposed on the substrate 1 so that the main body of the electronic component 2 is spaced apart from the substrate 1 and faces the hole, such that the electronic component 2 is mounted on the mounting region 8 with solder 3 (ST2). As a result, a gap 9 is formed between the electronic component 2 and the substrate 1.

Next, as shown in (C) of FIG. 5, a coating agent 50 is dispensed and jet-applied (ST3) toward the electronic component 2 on the substrate 1 whose first surface 11 is oriented upwards from the side of the first surface 11 through a nozzle 70 and dried (ST4), such that a coating layer 5 is formed.

The jet coating is performed so that a dispensing direction of the coating agent 50 from the nozzle 70 is perpendicular to the first surface 11. This can suppress splashing of the coating agent 50.

In the present embodiment, forming the hole 4 in the substrate 1 enables the coating layer 5 to be formed to include no air-bubbles even with a coating agent 50 with relatively high viscosity, 20 millipascal seconds or more. In a case where the application is performed with such a high-viscosity coating agent 50, performing the application so that the dispensing direction of the coating agent is perpendicular to the first surface 11 can easily suppress splashing of the coating agent 50 and suppress adhesion of the coating agent to portions where the coating agent is wished not to be applied. Also in other embodiments which will be described later, the jet coating is favorably performed so that the dispensing direction of the coating agent from the nozzle 70 is perpendicular to the first surface 11 also in order to suppress scattering of the coating agent.

In the jet coating, as shown in FIG. 6, the coating agent 50 is applied to the electronic component 2 mounted on the mounting region 8 by relatively moving the nozzle 70 with respect to the substrate 1 in a plane direction (plane direction orthogonal to the thickness direction of the substrate). At the time of jet coating, only the nozzle 70 may be moved, only the substrate 1 may be moved, or both the nozzle 70 and the substrate 1 may be moved. Here, an example in which only the nozzle 70 is moved is described. In FIG. 6, a movement path on which the nozzle 70 moves with respect to the substrate 1 is denoted by the reference sign 72. In the example shown in FIG. 6, the range of movement of the nozzle 70 is a region slightly larger than the mounting region 8 for the electronic component 2. As shown in the movement path 72 in FIG. 6, the nozzle 70 moves downwards in FIG. 6 in a direction parallel to a shorter side of the electronic component 2 that is rectangular in the planar view, for example. Subsequently, the nozzle 70 moves upwards in FIG. 6 in a direction parallel to the shorter side of the electronic component 2 after it is slightly shift in a direction (in FIG. 6, the left-hand direction) parallel to a longer side of the electronic component 2. Then, the nozzle 70 repeats an operation in which the nozzle 70 moves downwards in FIG. 6 after it is slightly shifted in the left-hand direction. In this manner, the nozzle 70 reciprocates in the upper and lower directions and applies the coating agent 50 to a region slightly larger than the mounting region 8 while being slightly shifted in the left-hand direction in FIG. 6. By applying the coating agent 50 in this manner, the coating layer 5 is formed to cover the entire electronic component 2 as shown in (D) of FIG. 5.

At the time of applying the coating agent 50, the coating agent 50 dispensed in vicinity of the outer periphery of the electronic component 2 diffuses in the plane direction on the substrate 1. The gap 9 between the substrate 1 and the main body of the electronic component 2 is narrow, approximately 0.1 mm to 0.3 mm, and the coating agent 50 dispensed in vicinity of the outer periphery of the mounting region 8 enters the gap 9 due to the capillary action. In the planar view, the applied coating agent 50 diffuses toward the center of the electronic component 2 from the vicinity of the outer periphery of the electronic component 2 inside the gap 9. In the present embodiment, since the mounting region 8 has the hole 4, the air in the gap 9 easily escapes from the side of the second surface 12 to the outside of the substrate 1 through the hole 4 while the coating agent 50 entering the gap 9 is diffusing inside the gap 9.

Accordingly, the coating agent 50 is filled so that no air-bubbles remain in the gap 9, and the electronic component 2 can be mounted so that no air-bubbles are generated in the coating layer 5 disposed in the gap 9 as shown in (D) of FIG. 5. Thus, cracks are not easily generated in the coating layer 5, and the occurrence of moisture invasion, and thus a failure such as a short-circuit which could be caused by cracks can be suppressed.

Curtain coating may be used for applying the coating agent other than the above-mentioned jet coating. Moreover, a contact type method may be used other than con-tactless application methods such as jet coating and curtain coating. Jet coating which enables high-accuracy control on the application range is more favorably used for applying the coating agent.

In the jet coating described above, a liquid coating agent can be applied under fine control by spraying it to one surface of the substrate 1 through the tip end of the nozzle 70 and controlling the thickness in a desired limited range. Since the jet coating can limit the application range in this manner, the coating agent can be prevented from being adhered to portions where application of the coating agent is wished to be avoided. Examples of the portions where application of the coating agent is wished to be avoided can include a connector mounted on the substrate 1, peripheries of screw holes of the substrate 1 which electrically connect to a casing chassis, test points which electrically connect to test equipment, and a gasket and a clip for electromagnetic compatibility (EMC). Moreover, the utilization efficiency of the coating agent can be improved because the jet coating enables high-accuracy control on the amount of application.

### Details of Coating Agent

Forming the coating layer 5 on the electronic component 2 can prevent condensation, moisture invasion, and the like of the electronic component 2 which induces a failure such as short-circuit and current leakage of the electronic component.

A resin having damp-proofness and insulation can be used as the coating agent for preventing those failures in advance. For example, a polyvinyl-based resin, a fluorine-based resin, a urethane-based resin, an acrylic-based resin, a silicon-based resin, or an olefin-based resin can be used.

In order to reliably apply the coating agent in a desired limited range on the substrate 1, the viscosity of the coating agent at the time of application is favorably 20 millipascal seconds or more, and more favorably 50 millipascal seconds or more. Setting the viscosity to be 20 millipascal seconds or more can suppress excessive diffusion of the coating agent at the time of applying the coating agent, and the coating agent can be reliably applied in a desired limited range.

Here, as the viscosity of the coating agent increases, the coating agent can be applied in a desired limited range and the electronic component can be more reliably covered with the coating layer, and a highly reliable electronic component can be provided. However, as the viscosity of the coating agent increases, the coating agent does not easily diffuse in the gap 9 between the substrate 1 and the electronic component 2 at the time of applying the coating agent, and the air-bubbles (air stagnation) are easily generated.

In the present embodiment, forming the hole 4 enables the air in the gap 9 to easily escape from the side of the second surface 12 through the hole 4 at the time of applying the coating agent, and the mounting board 10 that suppresses generation of air-bubbles in the coating layer can be provided.

Forming the hole 4 can suppress generation of air-bubbles even with a coating agent with high viscosity, e.g., 100 millipascal seconds or more. In addition, as it will be described later in a fifth embodiment, suctioning the air in the gap 9 from the side of the second surface 12 through the hole 4 at the time of applying the coating agent can more reliably suppress generation of air-bubbles at the time of applying a high-viscosity coating agent.

While reliably applying the coating agent in a desired limited range of the electronic component 2, the coating agent at the time of application has viscosity of favorably 20 millipascal seconds or more or 100 millipascal seconds or less, and more favorably has 50 millipascal seconds or more or 80 millipascal seconds or less in order to cause the coating agent 50 to favorably diffuse inside the gap 9.

In the present embodiment, a coating agent containing a polyvinyl-based resin as a main component and having viscosity of 55 millipascal seconds (20° C.) was used.

### Hole Size and Hole Arrangement

A size of the hole 4 and an arrangement of the hole 4 in each electronic component 2 will be described. It should be noted that here, an example in which the outer shape of the hole 4 in the planar view is a perfect circle shape is described, though not limited thereto. For example, the outer shape of the hole 4 in the planar view may be a polygonal shape or an elliptical shape. Here, since the example in which the shape of the hole 4 in the planar view is the perfect circle shape is described, the “hole size” is expressed as a diameter of the hole 4. As to a hole having a shape other than the perfect circle shape, the hole size is expressed as a length of the longest line segment among line segments connecting two cross points at which a straight line crosses the outer shape of the hole when drawing the straight line passing through the center of the outer shape of the hole on the outer shape of the hole in the planar view. For example, in a case where the shape of the hole 4 is elliptical, the size of the hole 4 can be expressed as a major axis.

Specific numeric values associated with the hole size and the hole arrangement described below can be adjusted as appropriate, variable depending on viscosity, application conditions, or the like of a used coating agent (a resin for forming a coating layer). It should be noted that the “viscosity of the coating agent” is the viscosity of the coating agent when the coating agent is actually applied.

In a case where the coating agent is applied to the first surface 11 of the substrate 1 by jet coating, for example, the hole size and the hole arrangement can be set as follows.

Referring to (B) of FIG. 2 and (B) of FIG. 3, the diameter (hole size) of a hole 4a is favorably 0.1 mm or more, and more favorably 0.2 mm or more in order to allow the air to escape through the gap 9 when the coating agent 50 is applied from the side of the first surface 11.

In order to prevent the coating agent fed to the first surface 11 from flowing on the hole 4 and dropping from the side of the second surface 12, the diameter of the hole 4a is favorably a minute size so that the capillary action occurs inside the hole 4 due to the surface tension of the coating agent. With such a configuration, the coating agent does not easily drop from the side of the second surface 12 of the substrate 1, and the gap 9 can be reliably filled with the coating agent.

As described above, the coating agent 50 in the gap 9 easily gradually diffuses toward the center of the electronic component 2 from the vicinity of the outer periphery of the electronic component 2 in the planar view at the time of applying the coating agent 50. Therefore, for example, in a case where a single hole 4 is formed, the hole 4 is favorably disposed at the vicinity of the center of the mounting region 8 as shown in (B) of FIG. 2 in order to allow the air in the gap 9 to easily and more reliably escape from the side of the second surface 12 to the outside of the substrate 1 through the hole 4. In a case where a plurality of holes 4 is formed in the mounting region 8, the holes 4 are favorably arranged so that the center of a hole group constituted by the plurality of holes 4 is positioned at the vicinity of the center of the mounting region 8 as shown in (B) and (C) of FIG. 3 for a purpose similar to the above-mentioned purpose.

Referring to (B) of FIG. 3, in a case where the plurality of holes 4 is formed in the mounting region 8, the holes 4 are favorably formed so that a pitch h between the holes 4 (a center-to-center distance between the holes adjacent to each other) is 3 mm or less, and more favorably 2 mm or less. Accordingly, the air in the gap 9 between the electronic component 2 and the substrate 1 can be allowed to effectively escape through the hole at the time of applying the coating agent.

The lower limit value of the pitch h between the holes 4 is not particularly limited. It is sufficient to form the holes 4 so as to avoid lands and a wiring pattern formed on the substrate 1 and prevent lowering of the strength of the entire mounting board 10.

The number of holes 4 can be set as appropriate depending on the size and the like of the electronic component 2. Although the air in the gap 9 can escape more easily along with an increase in number of holes, the holes 4 are favorably arranged so that the number of holes becomes minimum within a range in which generation of air-bubbles in the coating layer 5 can be suppressed in order to achieve high-density mounting of the electronic component.

Referring to (B) and (C) of FIG. 3, in a case where the plurality of holes 4 is formed in the mounting region 8, the holes 4 are favorably formed so that as to an outermost hole of the plurality of holes 4 as viewed from the center of the mounting region 8, a distance g from the outline of the region 85 corresponding to the main body 63 is 1 mm or less, and more favorably 0.5 mm or less in order to allow the air in the gap 9 between the electronic component 2 and the substrate 1 to effectively escape to the outside of the substrate 1 through the hole 4.

The “outermost hole of the plurality of holes 4 as viewed from the center of the mounting region 8” corresponds to each of the four holes 4 in the example shown in (B) of FIG. 3 and corresponds to each of the four holes 4 excluding the hole disposed at the center in the example shown in (C) of FIG. 3.

The hole(s) 4 is formed in the region corresponding to the main body of the mounting region 8 of the substrate 1 by employing the numeric values associated with the size of the hole 4 and the arrangement of the hole 4 within the above-mentioned numeric value ranges. Therefore, a plurality of holes 4 is formed in the mounting region 8 for the electronic component 2 having a relatively large size, such as the IC chip. On the other hand, one or two holes 4 are formed in the mounting region 8 for the electronic component 2 having a relatively small size, such as the chip resistor 2A.

For example, in the example shown in (B) of FIG. 3, a coating layer 5 is formed with a coating agent with viscosity of 55 millipascal seconds with respect to the IC chip 2B with leads whose main body 63 has a size of 4 mm*5 mm (the horizontal length d*the vertical length f). The four holes 4 may be formed in the mounting region 8 of the IC chip 2B with leads, the diameter of the hole 4a may be 0.2 mm, and the pitch h between the holes 4 may be 2 mm.

### Second Embodiment

### Configuration of Mounting Board

FIG. 7 is a schematic partial cross-sectional view of a mounting board 10A according to a second embodiment. As shown in FIG. 7, the mounting board 10A is a mounting board for double-sided mounting. The mounting board 10A includes a substrate 1 having a first hole 41 and a second hole 42, a first electronic component 21, first solder 31, a first coating layer 51, a second electronic component 22, second solder 32, and a second coating layer 52.

The substrate 1 has a first surface 11 and a second surface 12. The first electronic component 21 is mounted on the first surface 11. The second electronic component 22 is mounted on the second surface 12. The first hole 41 is formed in a first mounting region 81 of the first electronic component 21 mounted on the first surface 11. The second hole 42 is formed in a second mounting region 82 of the second electronic component 22 mounted on the second surface 12. The first coating layer 51 is formed by applying a first coating agent toward the first electronic component 21 from the side of the first surface 11 in a state in which the first surface 11 of the substrate 1 is oriented upwards. The second coating layer 52 is formed by applying a second coating agent toward the second electronic component 22 from the side of the second surface 12 in a state in which the second surface 12 of the substrate 1 is oriented upwards.

In a case of the double-sided mounting, as shown in FIG. 7, each electronic component is favorably mounted so that the first mounting region 81 of the first electronic component 21 and the second mounting region 82 of the second electronic component 22 do not overlap each other in the thickness direction of the substrate 1, in other words, do not overlap each other in the planar view. Accordingly, the first hole 41 and the second hole 42 can effectively suppress generation of air-bubbles at the time of applying the first coating agent and the second coating agent.

### Manufacturing Method for Mounting Board

Next, a manufacturing method for the mounting board 10A according to the present embodiment will be described. FIG. 8 is a flowchart showing the manufacturing method for the mounting board 10A. Hereinafter, it will be described following the flowchart in FIG. 8.

First of all, a substrate 1 is prepared and a first hole 41 and a second hole 42 are formed to penetrate the substrate 1 in the thickness direction in a first mounting region 81 provided in a first surface 11 of the substrate 1 and a second mounting region 82 provided in a second surface 12, respectively (ST10). The holes 4 can be formed by drilling. The first mounting region 81 is a region where the first electronic component 21 is mounted on the first surface 11 of the substrate 1. The second mounting region 82 is a region where the second electronic component 22 is mounted on the second surface 12 of the substrate 1.

Next, the substrate 1 is placed so that the first surface 11 is upper and the second surface 12 is lower, and the first electronic component 21 is mounted on the first mounting region 81 with first solder 31 (ST11). As a result, a gap 9 is formed between the first electronic component 21 and the substrate 1.

Next, the substrate 1 is placed so that the first surface 11 is lower and the second surface 12 is upper by turning over the substrate 1. Subsequently, the second electronic component 22 is mounted on the second mounting region 82 with second solder 32 (ST12). As a result, a gap 9 is formed between the second electronic component 22 and the substrate 1.

A relatively light electronic component 2 is mounted on the first surface 11 and a relatively heavy electronic component 2 is mounted on the second surface 12. In the mounting board for double-sided mounting, a reflow process of melting the solder and electrically connecting the electronic component and the substrate to each other is performed twice. The first surface 11 is placed facing downwards when mounting the electronic component 2 on the second surface 12. Since the relatively light electronic component 2 is mounted on the first surface 11, a phenomenon that the electronic component falls from the substrate 1 due to its own weight is unlikely to occur even if the solder applied to the first surface 11 is molten in the reflow process when mounting the electronic component on the second surface 12 because the electronic component already mounted on the first surface 11 is light.

Next, as in the first embodiment, a second coating agent is dispensed and jet-applied through the nozzle toward the second electronic component 22 from the side of the second surface 12 of the substrate 1 (ST13) and dried (ST14), and a second coating layer 52 is formed to cover the entire second electronic component 22.

Next, the substrate 1 is disposed by turning over the substrate 1 so that the first surface 11 becomes an upper surface and the second surface 12 becomes a lower surface. Subsequently, as in the first embodiment, the first coating agent is dispensed and jet-applied through the nozzle toward the first electronic component 21 from the side of the first surface 11 of the substrate 1 (ST15) and dried (ST16), and a first coating layer 51 is formed to cover the entire first electronic component 21.

Also in the present embodiment, as in the first embodiment, the air in the gap 9 easily escapes from the side of the second surface 12 (the side of the first surface 11) to the outside of the substrate 1 through the first hole 41 (second hole 42) while the first coating agent (second coating agent) entering the gap 9 between the first electronic component 21 (second electronic component 22) and the substrate 1 is diffusing inside the gap 9 at the time of applying the first coating agent (second coating agent) because the first hole 41 (second hole 42) is formed in the first mounting region 81 (second mounting region 82). Accordingly, the first coating agent (second coating agent) is applied so that no air-bubbles remain in the gap 9, and as shown in FIG. 7, the first electronic component 21 (second electronic component 22) can be mounted so that no air-bubbles are generated in the first coating layer 51 (second coating layer 52) disposed in the gap 9. Thus, cracks are not easily generated in the first coating layer 51 (second coating layer 52), and the occurrence of moisture invasion, and thus a failure such as a short-circuit which could be caused by cracks can be suppressed.

### Third Embodiment

In the above-mentioned embodiment, the coating layer is formed with one-time application of the coating agent to the single electronic component 2, though not limited thereto. Hereinafter, in the present embodiment and the fourth embodiment which will be described later, an example in which a coating layer is formed by twice application of a coating agent will be described.

FIG. 9 is a flowchart showing a manufacturing method for a mounting board 10B according to the third embodiment. FIG. 10 is a schematic cross-sectional view showing a manufacturing process for the mounting board 10B. Hereinafter, the manufacturing method for the mounting board 10B will be described with reference to FIG. 10 following the flowchart of FIG. 9.

As shown in (A) of FIG. 10, first of all, a substrate 1 is prepared and a hole 4 is formed to penetrate the substrate 1 in a thickness direction in a mounting region 8 set in a first surface 11 of the substrate 1 (ST20).

Next, as shown in (B) of FIG. 10, the electronic component 2 is mounted on the mounting region 8 with solder 3 (ST21). As a result, a gap 9 is formed between the electronic component 2 and the substrate 1.

Next, as shown in (C) of FIG. 10, a gap coating agent 73 is dispensed and jet-applied toward the electronic component 2 on the substrate 1 whose first surface 11 is oriented upwards from the side of the first surface 11 through the nozzle 70 (ST22) and dried (ST23). As a result, a gap coating layer 6 is formed as shown in (D) of FIG. 10. The gap coating layer 6 is disposed to fill at least a gap 9 between the substrate 1 and the electronic component 2. In the example shown in (D) of FIG. 10, the gap coating layer 6 is formed to fill the gap 9 and surround the electronic component 2.

In the application of the gap coating agent 73, as in the first embodiment, the nozzle 70 is relatively moved with respect to the substrate 1 in a plane direction (plane direction orthogonal to the thickness direction of the substrate) and the gap coating agent 73 is applied to the mounting region 8. The range of movement of the nozzle 70 is a region slightly larger than the mounting region 8 for the electronic component 2. As in a movement path 72 shown in FIG. 6, the gap coating agent 73 is applied to a region slightly larger than the mounting region 8 while gradually shifting the nozzle 70 in the left-hand direction in FIG. 6 and reciprocating the nozzle 70 in the upper and lower directions.

The gap coating agent 73 is a coating agent with lower viscosity. A coating agent with viscosity of 0.5 millipascal seconds to 10 millipascal seconds can be used as the coating agent with lower viscosity. By using the coating agent with lower viscosity in the first application of the coating agent (gap coating agent) as such, the gap coating agent 73 can quickly and reliably diffuse inside the gap 9. Then, since the mounting region 8 has the hole 4, the air in the gap 9 easily escapes to the outside of the substrate 1 from the side of the second surface 12 through the hole 4 while the gap coating agent entering the gap 9 is diffusing inside the gap 9. Accordingly, filling with the gap coating agent 73 is performed so that no air-bubbles remain in the gap 9, and as shown in (D) of FIG. 10, air-bubbles can be prevented from being generated in the gap coating layer 6 disposed in the gap 9.

It should be noted that although the gap coating agent is not applied to the upper surface of the electronic component 2 in FIG. 10, it may be applied thereto. In a case of using the gap coating agent 73 with lower viscosity, it easily diffuses in the plane direction, and thus it is difficult to form a coating layer with a thickness on the upper surface of the electronic component 2. In contrast, in the present embodiment, the entire electronic component 2 can be reliably covered by using a coating agent with higher viscosity in the second application of a coating agent (cover coating agent) which will be described later.

Next, as shown in (E) of FIG. 10, a cover coating agent 74 is dispensed and jet-applied toward the electronic component 2 from the side of the first surface 11 of the substrate 1 through the nozzle 70 (ST24) and dried (ST25). As a result, a cover coating layer 7 is formed as shown in (F) of FIG. 10. The cover coating layer 7 is formed to cover the entire electronic component 2 on which the gap coating layer 6 formed surrounding the gap 9 and the electronic component 2 has been formed. The cover coating layer 7 and the gap coating layer 6 constitute a coating layer 5B.

In application of the cover coating agent 74, as in the first embodiment, the cover coating agent 74 is applied to the mounting region 8 by relatively moving the nozzle with respect to the substrate 1 in a plane direction (plane direction orthogonal to the thickness direction of the substrate). The range of movement of the nozzle 70 is a region larger than the range of movement when the gap coating agent 73 is applied. Also as to the movement path at this time, as in the movement path 72 shown in FIG. 6, the cover coating agent 74 is applied while gradually shifting the nozzle 70 in the left-hand direction in FIG. 6 and reciprocating the nozzle 70 in the upper and lower directions so as to cover the entire electronic component 2 including the gap coating agent 73.

The cover coating agent 74 is a coating agent with higher viscosity than the viscosity of the gap coating agent 73. A coating agent with viscosity of 20 millipascal seconds to 100 millipascal seconds can be used as the coating agent with higher viscosity. By using the coating agent with higher viscosity in the second application of the coating agent (cover coating agent) as such, the coating agent does not easily diffuse in the plane direction, and the coating layer can be reliably formed on the upper surface of the electronic component 2, and the entire electronic component 2 can be reliably covered with the coating layer 5B.

The same type of resin may be used or different types of resin may be used as the gap coating agent and the cover coating agent.

The coating layer 5B may be formed in the second application process as described above. Using the gap coating agent 73 with lower viscosity in the first application enables the gap 9 to be reliably filled with the gap coating agent 73 so that no air-bubbles remain. Using the high-viscosity cover coating agent 74 in the second application thereafter enables the entire electronic component 2 to be reliably covered with the cover coating layer 7.

As described above, in the mounting board 10B according to the present embodiment, the electronic component 2 can be mounted so that the coating layer 5B disposed in the gap 9 contains no air-bubbles. Thus, cracks are not easily generated in the coating layer 5B, and the occurrence of moisture invasion, and thus a failure such as a short-circuit which could be caused by cracks can be suppressed.

### Fourth Embodiment

FIG. 11 is a flowchart showing a manufacturing method 10C for a mounting board according to the fourth embodiment. FIG. 12 is a schematic cross-sectional view showing a manufacturing process for the mounting board 10C. (A) of FIG. 13 is a plan view showing a state in which a wall coating agent is applied to the substrate 1 on which the electronic component 2 is mounted, which shows a movement path example of the nozzle. (B) of FIG. 13 is a plan view showing a state in which a cover coating agent is applied to the substrate 1 on which the electronic component 2 is mounted, which shows a movement path example of the nozzle. FIG. 14 is a partial schematic plan view of the mounting board 10C, which is a view describing a form of the coating layer. Hereinafter, the manufacturing method for the mounting board 10C will be described with reference to FIGS. 12 to 14 following the flowchart of FIG. 11.

As shown in (A) of FIG. 12, first of all, a substrate 1 is prepared and a hole 4 is formed to penetrate the substrate 1 in a thickness direction in a mounting region 8 set in a first surface 11 of the substrate 1 (ST30).

Next, as shown in (B) of FIG. 12, the electronic component 2 is mounted on the mounting region 8 with solder 3 (ST31). As a result, a gap 9 is formed between the electronic component 2 and the substrate 1.

Next, as shown in (C) of FIG. 12, a wall coating agent 75 is dispensed and jet-applied toward the electronic component 2 on the substrate 1 whose first surface 11 is oriented upwards from the side of the first surface 11 through the nozzle 70 (ST32) and dried (ST34).

In application of the wall coating agent 75, the nozzle is relatively moved with respect to the substrate 1 in a plane direction (plane direction orthogonal to the thickness direction of the substrate), and the wall coating agent 75 is applied so as to surround the electronic component 2 (in other words, so as to surround the mounting region 8, slightly spaced apart from the mounting region 8 in the plane direction). As shown in (A) of FIG. 13, a movement path 77 for the nozzle 70 to apply the wall coating agent 75 draws a rectangle surrounding the electronic component 2. As a result, a coating layer 30 having a wall-like shape (hereinafter, referred to as a wall-like coating layer 30) is formed surrounding the electronic component 2 as shown in (D) of FIG. 12 and (B) of FIG. 13.

The wall coating agent 75 is a coating agent with higher viscosity. A coating agent with viscosity of 20 millipascal seconds to 100 millipascal seconds can be used as the coating agent with higher viscosity. By using the coating agent with higher viscosity in the first application of the coating agent (wall coating agent) as such, the wall-like coating layer 30 can be formed to have a height in a desired limited range on the substrate 1. In order to reliably prevent a cover coating agent 76 which will be described later from diffusing in the plane direction, the position of the upper portion of the wall-like coating layer 30 is favorably substantially equal to or slightly larger in height than the position of the upper surface of the mounted electronic component 2.

Next, as shown in (E) of FIG. 12, the cover coating agent 76 is dispensed and jet-applied toward the electronic component 2 from the side of the first surface 11 of the substrate 1 through the nozzle 70 (ST34) and dried (ST35). As a result, a cover coating layer 34 is formed as shown in (F) of FIG. 12. The cover coating agent 76 is applied to the inside of the region surrounded by the wall-like coating layer 30. An amount of cover coating agent 76 is applied so as to prevent the cover coating agent 76 from becoming higher than the wall-like coating layer 30 and flowing out from the region surrounded by the wall-like coating layer 30. Applying the cover coating agent 76 forms the cover coating layer 34 that covers the entire electronic component 2 surrounded by the wall-like coating layer 30. The cover coating layer 34 and the wall-like coating layer 30 constitute a coating layer 5C.

In application of the cover coating agent 76, as in the first embodiment, the cover coating agent 76 is applied to the mounting region 8 by relatively moving the nozzle with respect to the substrate 1 in a plane direction (plane direction orthogonal to the thickness direction of the substrate). As shown in (B) of FIG. 13, the range of movement of the nozzle 70 is a region surrounded by the wall-like coating layer 30. As to a movement path 78 for the nozzle 70 to apply the cover coating agent 76, as in the movement path 72 shown in FIG. 6, the cover coating agent 76 is applied while gradually moving the nozzle 70 in the left-hand direction in FIG. 6 and reciprocating the nozzle 70 in the upper and lower directions so as to cover the entire electronic component 2 in the wall-like coating layer 30.

The cover coating agent 76 is a coating agent with lower viscosity than the wall coating agent 75. A coating agent with viscosity of 0.5 millipascal seconds to 10 millipascal seconds can be used as the coating agent with lower viscosity. By using the coating agent with lower viscosity in the second application of the coating agent (cover coating agent) as such, the coating agent easily diffuses in the plane direction, and the cover coating agent 76 can quickly and reliably diffuse inside the gap 9. Then, since the mounting region 8 has the hole 4, the air in the gap 9 easily escapes to the outside of the substrate 1 from the side of the second surface 12 through the hole 4 while the cover coating agent 76 entering the gap 9 is diffusing inside the gap 9. Accordingly, filling of the cover coating agent 76 is performed so that no air-bubbles remain in the gap 9, and no air-bubbles can be generated in the cover coating layer 34 disposed in the gap 9 as shown in (F) of FIG. 12.

The same type of resin or different types of resin may be used as the wall coating agent and the cover coating agent.

In addition, in the present embodiment, the wall-like coating layer 30 can block the cover coating agent 76 so that the cover coating agent 76 does not flow out of the wall-like coating layer 30. Therefore, the cover coating layer 34 can be formed in a desired limited range even with the coating agent with lower viscosity.

In this manner, the coating layer 5C may be formed in the second application process. Forming the wall-like coating layer 30 with the wall coating agent 75 with higher viscosity in the first application process can reliably suppress diffusion of the secondarily applied cover coating agent 76 in the plane direction. In addition, using the cover coating agent 76 with lower viscosity in the second application process enables the gap 9 to be reliably filled with the coating layer without generating air-bubbles, and the entire electronic component 2 can be reliably covered with the cover coating layer 34.

As described above, in the mounting board 10C according to the present embodiment, the electronic component 2 can be mounted so that the gap 9 contains no air-bubbles. Thus, cracks are not easily generated in the coating layer 5C, and the occurrence of moisture invasion, and thus a failure such as a short-circuit which could be caused by cracks can be suppressed.

### Fifth Embodiment

FIG. 15 is a view describing a manufacturing method for a mounting board according to the fifth embodiment. In each of the above-mentioned embodiments, when the coating agent is applied to the electronic component 2 mounted on the side of the first surface 11 (or the side of the second surface 12), the air in the gap 9 between the electronic component 2 and the substrate 1 may be suctioned through the hole 4 from the side of the second surface 12 (or the side of the first surface 11) as shown in FIG. 15. This can accelerate filling of the gap 9 with the coating agent and suppress generation of air-bubbles in the coating layer because the air in the gap 9 is actively discharged to the outside of the gap 9.

### Sixth Embodiment

FIG. 16 is a view describing a manufacturing method for a mounting board according to a sixth embodiment. In a case where a coating agent that tends to increase in viscosity due to cooling for example is used as the coating agent, as shown in FIG. 16, a heater 13 may be disposed on a top surface side opposite to the surface to which the coating agent is applied (in the example shown in FIG. 16, the side of the second surface 12) when the coating agent is applied to the electronic component 2. The viscosity of the coating agent may be adjusted to be desired viscosity by heating with the heater 13. Moreover, although the example in which the coating agent is heated from the lower side of the substrate 1 has been described in the example shown in FIG. 16, the coating agent may be heated from the upper side. The heating temperature is adjusted as appropriate depending on a coating agent to be used.

### OTHER EXAMPLES

Hereinabove, the embodiments of the present technology have been described. However, the present technology is not limited to those embodiments and various modifications can be made without departing from the gist of the present technology as a matter of course.

The present technology can also take the following configurations.
(1) A manufacturing method for a mounting board, including:
forming a hole in a mounting region of a substrate, the hole penetrating the substrate in a thickness direction of the substrate, the substrate having a first surface and a second surface and having the mounting region on the first surface;
mounting an electronic component on the mounting region by disposing a main body of the electronic component so that the main body is spaced apart from the substrate and faces the hole, the electronic component having the main body and a connection part; and
forming a coating layer that covers the entire electronic component including a gap between the substrate and the electronic component by applying a coating agent toward the electronic component from a side of the first surface with the first surface oriented upwards.
(2) The manufacturing method for a mounting board according to (1), in which
the coating agent enters at least a part of the hole at the time of forming the coating layer.
(3) The manufacturing method for a mounting board according to (1) or (2), further including
suctioning air in the gap from a side of the second surface through the hole at the time of forming the coating layer.
(4) The manufacturing method for a mounting board according to any one of (1) to (3), in which
the coating agent has viscosity of 20 millipascal seconds or more.
(5) The manufacturing method for a mounting board according to any one of (1) to (4), in which
the coating layer includes a gap coating layer and a cover coating layer, and
the forming the coating layer includes
forming the gap coating layer at least in the gap by applying a gap coating agent toward the electronic component from the side of the first surface, and
forming the cover coating layer that covers the entire electronic component including the gap coating layer by applying a cover coating agent toward the electronic component from the side of the first surface, the cover coating agent having viscosity higher than viscosity of the gap coating agent.
(6) The manufacturing method for a mounting board according to any one of (1) to (4), in which
the coating layer includes a wall-like coating layer and a cover coating layer, and the forming the coating layer includes
forming the wall-like coating layer that surrounds the electronic component by applying a wall coating agent to the substrate from the side of the first surface so as to surround the mounting region, and
forming the cover resin layer that covers the entire electronic component including the gap by applying a cover coating agent to a region surrounded by the wall-like coating layer from the side of the first surface, the cover coating agent having viscosity lower than viscosity of the wall coating agent.
(7) The manufacturing method for a mounting board according to any one of (1) to (6), in which
the substrate has a mounting region on the second surface, the mounting region not overlapping the mounting region on the first surface in the thickness direction, the manufacturing method further including:
forming a hole in the mounting region on the second surface of the substrate, the hole penetrating the substrate in the thickness direction;
mounting an electronic component to be mounted on the second surface on the mounting region on the second surface by disposing a main body of the electronic component to be mounted on the second surface so that the main body is spaced apart from the substrate and faces the hole in the mounting region on the second surface, the electronic component to be mounted on the second surface having the main body and a connection part; and
forming a coating layer that covers the entire electronic component to be mounted on the second surface including a gap between the substrate and the electronic component to be mounted on the second surface by applying a coating agent toward the electronic component to be mounted on the second surface from a side of the second surface with the second surface oriented upwards.
(8) The manufacturing method for a mounting board according to any one of (1) to (7), further including
heating the substrate at the time of forming the coating layer.
(9) The manufacturing method for a mounting board according to any one of (1) to (8), in which
the applying the coating agent is jet coating, and
a dispensing direction of the coating agent is perpendicular to the first surface.
(10) A mounting board, including:
a substrate having a first surface and a second surface, having a mounting region on the first surface, and having a hole in the mounting region, the hole penetrating the substrate in a thickness direction of the substrate;
an electronic component that has the main body and a connection part and is mounted on the mounting region by disposing the main body so that the main body is spaced apart from the substrate and faces the first hole; and
a coating layer that is formed on the first surface and covers the entire electronic component including a gap between the substrate and the electronic component.
(11) The mounting board according to (10), in which the coating layer enters at least a part of the hole.
(12) The mounting board according to (10) or (11), in which the coating layer includes
a gap coating layer that is disposed including the gap, and
a cover coating layer that covers the entire electronic component including the gap coating layer.
(13) The mounting board according to (10) or (11), in which
the coating layer includes
a wall-like coating layer having a wall-like shape that surrounds the electronic component disposed on the substrate, and
a cover coating layer that is located inside a region surrounded by the wall-like coating layer and covers the electronic component.
(14) The mounting board according to any one of (10) to (13), in which the substrate has a mounting region on the second surface and has a hole in the mounting region on the second surface, the mounting region not overlapping the mounting region on the first surface in the thickness direction, the hole penetrating the substrate in the thickness direction of the substrate, the mounting board further including:
an electronic component to be mounted on the second surface that has a main body and a connection part and is mounted on a mounting region on the second surface by disposing the main body so that the main body is spaced apart from the substrate and faces the hole in the mounting region on the second surface; and
a coating layer that is formed on the second surface and covers the entire electronic component to be mounted on the second surface including a gap between the substrate and the electronic component to be mounted on the second surface.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 Substrate
2 Electronic component
2A Chip resistor (electronic component)
2B IC chip with leads (electronic component)
2C IC chip with no leads (electronic component)
4 Hole, first hole
5, 5B, 5C Coating layer
6 Gap coating layer
7 Cover coating layer
8 Mounting region
9 Gap
10, 10A, 10B, 10C Mounting board
11 First surface
12 Second surface
21 First electronic component (electronic component)
22 Second electronic component (electronic component to be mounted on second surface)
30 Wall-like coating layer
34 Cover coating layer
41 First hole (hole)
42 Second hole (hole of mounting region on second surface)
50 Coating agent
51 First coating layer (coating layer)
52 Second coating layer (coating layer that covers entire electronic component to be mounted on second surface)
60, 63 Main body
61 External electrode (connection portion)
64 Leads (connection portion)
65 External electrode (connection portion)
73 Gap coating agent
74 Cover coating agent
75 Wall coating agent
76 Cover coating agent
81 First mounting region (mounting region on first surface)
82 Second mounting region (mounting region on second surface)

1. A manufacturing method for a mounting board, comprising:
forming a hole in a mounting region of a substrate, the hole penetrating the substrate in a thickness direction of the substrate, the substrate having a first surface and a second surface and having the mounting region on the first surface;
mounting an electronic component on the mounting region by disposing a main body of the electronic component so that the main body is spaced apart from the substrate and faces the hole, the electronic component having the main body and a connection part; and
forming a coating layer that covers the entire electronic component including a gap between the substrate and the electronic component by applying a coating agent toward the electronic component from a side of the first surface with the first surface oriented upwards.

2. The manufacturing method for a mounting board according to claim 1, wherein
the coating agent enters at least a part of the hole at the time of forming the coating layer.

3. The manufacturing method for a mounting board according to claim 1, further comprising
suctioning air in the gap from a side of the second surface through the hole at the time of forming the coating layer.

4. The manufacturing method for a mounting board according to claim 1, wherein
the coating agent has viscosity of 20 millipascal seconds or more.

5. The manufacturing method for a mounting board according to claim 1, wherein
the coating layer includes a gap coating layer and a cover coating layer, and
the forming the coating layer includes
forming the gap coating layer at least in the gap by applying a gap coating agent toward the electronic component from the side of the first surface, and
forming the cover coating layer that covers the entire electronic component including the gap coating layer by applying a cover coating agent toward the electronic component from the side of the first surface, the cover coating agent having viscosity higher than viscosity of the gap coating agent.

6. The manufacturing method for a mounting board according to claim 1, wherein
the coating layer includes a wall-like coating layer and a cover coating layer, and
the forming the coating layer includes
forming the wall-like coating layer that surrounds the electronic component by applying a wall coating agent to the substrate from the side of the first surface so as to surround the mounting region, and forming the cover resin layer that covers the entire electronic component including the gap by applying a cover coating agent to a region surrounded by the wall-like coating layer from the side of the first surface, the cover coating agent having viscosity lower than viscosity of the wall coating agent.

7. The manufacturing method for a mounting board according to claim 1, wherein
the substrate has a mounting region on the second surface, the mounting region not overlapping the mounting region on the first surface in the thickness direction, the manufacturing method further comprising:
forming a hole in the mounting region on the second surface of the substrate, the hole penetrating the substrate in the thickness direction; mounting an electronic component to be mounted on the second surface on the mounting region on the second surface by disposing a main body of the electronic component to be mounted on the second surface so that the main body is spaced apart from the substrate and faces the hole in the mounting region on the second surface, the electronic component to be mounted on the second surface having the main body and a connection part; and
forming a coating layer that covers the entire electronic component to be mounted on the second surface including a gap between the substrate and the electronic component to be mounted on the second surface by applying a coating agent toward the electronic component to be mounted on the second surface from a side of the second surface with the second surface oriented upwards.

8. The manufacturing method for a mounting board according to claim 1, further comprising
heating the substrate at the time of forming the coating layer.

9. The manufacturing method for a mounting board according to claim 1, wherein
the applying the coating agent is jet coating, and
a dispensing direction of the coating agent is perpendicular to the first surface.

10. A mounting board, comprising:
a substrate having a first surface and a second surface, having a mounting region on the first surface, and having a hole in the mounting region, the hole penetrating the substrate in a thickness direction of the substrate;
an electronic component that has the main body and a connection part and is mounted on the mounting region by disposing the main body so that the main body is spaced apart from the substrate and faces the first hole; and
a coating layer that is formed on the first surface and covers the entire electronic component including a gap between the substrate and the electronic component.

11. The mounting board according to claim 10, wherein the coating layer enters at least a part of the hole.

12. The mounting board according to claim 10, wherein the coating layer includes
a gap coating layer that is disposed including the gap, and
a cover coating layer that covers the entire electronic component including the gap coating layer.

13. The mounting board according to claim 10, wherein the coating layer includes
a wall-like coating layer having a wall-like shape that surrounds the electronic component disposed on the substrate, and a cover coating layer that is located inside a region surrounded by the wall-like coating layer and covers the electronic component.

14. The mounting board according to claim 10, wherein
the substrate has a mounting region on the second surface and has a hole in the mounting region on the second surface, the mounting region not overlapping the mounting region on the first surface in the thickness direction, the hole penetrating the substrate in the thickness direction of the substrate, the mounting board further comprising:
an electronic component to be mounted on the second surface that has a main body and a connection part and is mounted on a mounting region on the second surface by disposing the main body so that the main body is spaced apart from the substrate and faces the hole in the mounting region on the second surface; and
a coating layer that is formed on the second surface and covers the entire electronic component to be mounted on the second surface including a gap between the substrate and the electronic component to be mounted on the second surface.
